(19) United States
(12) Patent Application Publication
(10) Pub. No.: US 2012/0002491 A1
(43) Pub. Date: Jan. 5, 2012

(54) TEST SIGNAL GENERATING DEVICE, SEMICONDUCTOR MEMORY APPARATUS USING THE SAME AND MULTI-BIT TEST METHOD THEREOF

(75) Inventor: Hong Sok CHOI, Ichon-si (KR)

(73) Assignee: Hynix Semiconductor Inc., Ichon-si (KR)

(21) Appl. No.: 12/962,437

(22) Filed: Dec. 7, 2010

(30) Foreign Application Priority Data
Jul. 2, 2010 (KR) 10-2010-0064006

(51) Int. Cl. G11C 29/36

(52) U.S. Cl. 365/189.16; 365/201

(57) ABSTRACT

A semiconductor memory apparatus includes a multi-bit test signal generating device configured to receive an address signal and generate a multi-bit test signal based on the address signal when a multi-bit test write operation is performed.

### CROSS-REFERENCES TO RELATED APPLICATION

The present application claims priority under 35 U.S.C. §119(a) to Korean Application No. 10-2010-0064006, filed on Jul. 2, 2010, which is incorporated by reference in its entirety as if set forth in full.

### BACKGROUND OF THE INVENTION

1. Technical Field

Various embodiments relate to a semiconductor memory apparatus, and more particularly, to a test of the semiconductor memory apparatus.

2. Related Art

In order to ensure the reliability of a semiconductor apparatus, various tests are typically performed during the manufacturing process or at least prior to product distribution. Since the manufacturing cost is proportional to the testing duration, the testing time should be minimized as much as possible. A multi-bit test technique which minimizes the testing time for the semiconductor memory apparatus has recently been adopted. The multi-bit test is performed by inputting data through a single data pad and applying the data to a plurality of bit lines simultaneously while the data on the bit line is written in a memory cell.

FIG. 1 is a block diagram showing a configuration of a conventional semiconductor memory apparatus. As shown in FIG. 1, the conventional semiconductor memory apparatus includes a test signal generating unit 10, a data pad block 20, and a write driver 30. In order to perform a multi-bit test for the semiconductor memory apparatus, the test signal generating unit 10 receives a test signal TEST and generates first to third multi-bit test signals TBL<1:3>, that control the write driver 30. The data pad block 20 creates a path to input external data to the semiconductor memory apparatus. In FIG. 1, the data pad block 20 may be composed of four data pads, which are not shown. The write driver 30 amplifies first to fourth data bits D0 to D3 received from the data pad block 20 and transfers the amplified data to first to fourth bit lines BL0 to BL3, respectively.

The conventional semiconductor memory apparatus operates as follows. In a normal write operation, the write driver 30 amplifies the data D0 to D3 received from the plurality of data pads and transfers the amplified data to the corresponding bit lines BL0 to BL3, respectively. Therefore, the respective bit lines BL0 to BL3 may receive the data inputted through the data pads by way of the write driver 30. The data may then be stored in a memory cell (not shown) coupled to the corresponding bit lines BL0 to BL3, respectively.

In the test operation, when a multi-bit test operation is performed, the data D1 to D3 is not inputted. Only a single data bit D0 is inputted. The test signal generating unit 10 generates the first to third multi-bit test signals TBL<1:3> in response to the test signal TEST. The write driver 30 amplifies the data D0 and transfers the amplified data to the first bit line BL0. Meanwhile, in response to the multi-bit test signals TBL<1:3> and a test mode signal TXDQ, the write driver 30 may inversely or non-inversely amplify the data D0 and transfer it to the second to fourth bit lines BL1 to BL3. In response to the first multi-bit test signal TBL<1>, for example, inputted data D0 with a high logic level, may be driven inversely or non-inversely by the write driver 30 at the high logic level and transferred to the second bit line BL1. Likewise, in response to the second and third multi-bit test signals TBL<2:3>, the data D0 at the high logic level may be driven inversely or non-inversely and transferred to the third and fourth bit lines BL2 and BL3, respectively. Therefore, the write driver 30 has a configuration so that data with a desired logic level may be transferred to the respective bit lines based on a single data input.

The conventional semiconductor memory apparatus takes a considerable amount of time to perform a test because the semiconductor memory apparatus receives the test signal TEST to generate the multi-bit test signals TBL<1:3>. In other words, in order to change a pattern of the data transferred to the first to fourth bit lines BL0 to BL3 in the multi-bit test operation, the multi-bit test signals TBL<1:3> should be reset and the test signal TEST should be newly inputted to set the multi-bit test signals TBL<1:3>.

### SUMMARY OF THE INVENTION

The embodiments of the present invention include a test signal generating device capable of substantially reducing a test time, a semiconductor memory apparatus using the same, and a multi-bit test method thereof.

In one embodiment of the present invention, a semiconductor memory apparatus is provided that includes a multi-bit test signal generating device configured to receive an address signal and generate a multi-bit test signal based on the address signal when a multi-bit test write operation is performed.

In another embodiment of the present invention, a semiconductor memory apparatus includes: a multi-bit test signal generating unit configured to receive an address signal to generate a multi-bit test signal; and a write driver unit configured to receive a first data signal, a second data signal and the multi-bit test signal to generate a first input data signal and a second input data signal.

In still another embodiment of the present invention, a semiconductor memory apparatus includes: a multi-bit test signal generating unit configured to generate a plurality of multi-bit test signals in response to a plurality of address signals; and a write driver unit configured to inversely drive or non-inversely drive a single data signal to generate a plurality of input data signal in response to the plurality of multi-bit test signals.

In still another embodiment of the present invention, a multi-bit test method for a semiconductor memory apparatus includes: generating a multi-bit test signal based on an address signal which is used in an active operation of the semiconductor memory apparatus but not used in a write operation of the semiconductor memory apparatus, if a test mode signal and a write signal are enabled; inversely driving or non-inversely driving a first data signal to generate a plurality of input data signals in response to the multi-bit test signal; and transferring the plurality of input data signals to a plurality of bit lines.

### BRIEF DESCRIPTION OF THE DRAWINGS

Features, aspects, and embodiments are described in conjunction with the attached drawings, in which;

FIG. 1 is a block diagram showing a configuration of a conventional semiconductor memory apparatus;

FIG. 2 is a block diagram showing a configuration of a semiconductor memory apparatus according to an embodiment of the present invention;

FIG. 3 is a block diagram showing a configuration of a multi-bit test signal generating unit of FIG. 2;

FIG. 4 is a block diagram showing a configuration of a data pad block and a write driver unit of FIG. 2;

FIG. 5 is a diagram showing a configuration of a second input data generating unit of FIG. 4; and

FIG. 6 is a timing diagram showing an operation of the semiconductor memory apparatus according to the embodiment of the present invention.

### DETAILED DESCRIPTION OF THE PREFERRED EMBODIMENTS

Hereinafter, a test signal generating device and a semiconductor memory apparatus using the same and having a method of multi-bit testing thereof, according to the present invention, will be described below with reference to the accompanying drawings through preferred embodiments.

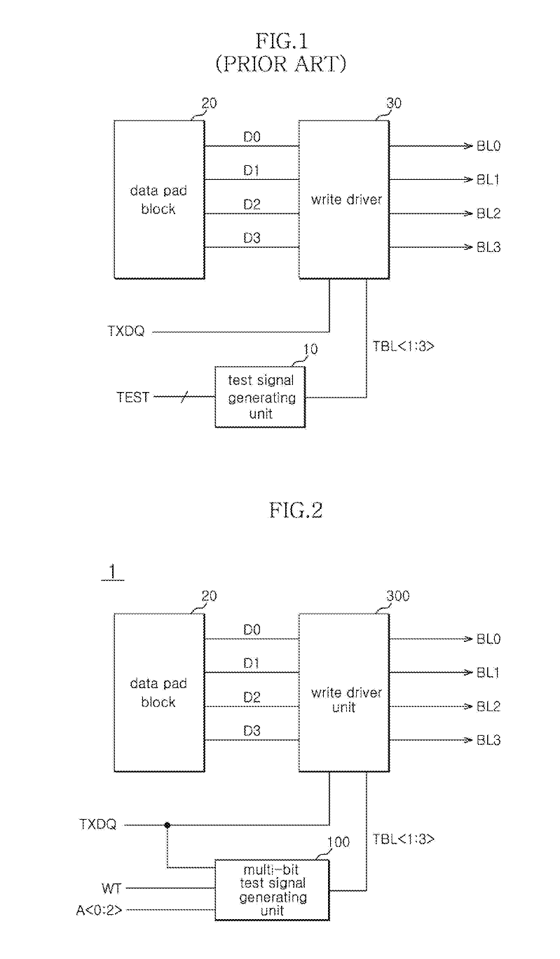

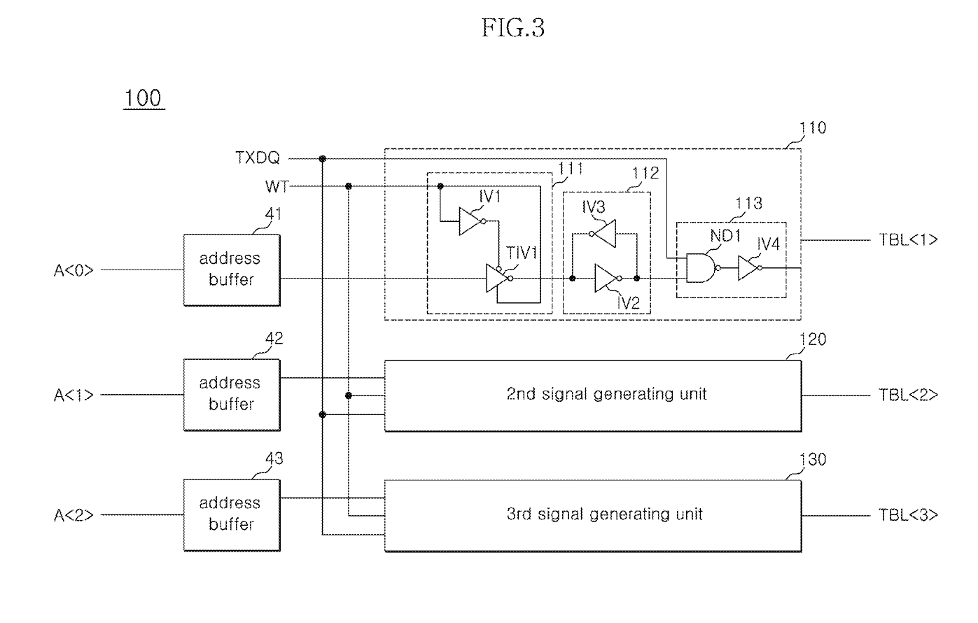

FIG. 2 is a block diagram showing a configuration of a semiconductor memory apparatus 1 according to one embodiment of the present invention. As shown in FIG. 2, the semiconductor memory apparatus 1 includes a data pad block 20, a multi-bit test signal generating unit 100, and a write driver unit 300. The multi-bit test signal generating unit 100 generates first to third multi-bit test signals TBL<1:3> from a plurality of address signals A<0:2>. In FIG. 2, the multi-bit test signal generating unit 100 receives the plurality of address signals A<0:2>, a write signal WT and a test mode signal TXDQ to generate the plurality of multi-bit test signals TBL<1:3>.

Any address signal inputted to the semiconductor memory apparatus 1 may be used as the address signals A<0:2>. Preferably, the address signals A<0:2> used in an active operation of the semiconductor memory apparatus 1 are not used in a write operation of the semiconductor memory apparatus 1. Since the semiconductor memory apparatus 1 generates the multi-bit test signals TBL<1:3> from the above-mentioned address signals A<0:2>, a test signal is inputted and signals are logically combined. Therefore, an extra operation that generates the multi-bit test signals TBL<1:3> is not required, rendering the system capable of substantially reducing the testing duration and enhancing the usefulness of the pads.

The write signal WT is an internally generated signal that informs the semiconductor memory apparatus 1 of the write operation when a write command is applied from the outside, e.g., a controller (not shown), to the semiconductor memory apparatus 1. The test mode signal TXDQ is a signal which informs the semiconductor memory apparatus 1 to perform not a normal write operation but a test operation, including a multi-bit test operation. In other words, if the test mode signal TXDQ is enabled, the semiconductor memory apparatus 1 performs the multi-bit test operation.

Since the multi-bit test signal generating unit 100 receives the test mode signal TXDQ and the write signal WT, the multi-bit test signal generating unit 100 may generate the multi-bit test signals TBL<1:3> based on the address signals A<0:2> in the write operation of the multi-bit test.

The data pad block 20 comprises a plurality of data pads, and is used as a path for the data inputted from the outside to be inputted to the inside of the semiconductor memory apparatus 1. Therefore, the data inputted from the outside is transferred to the write driver unit 300 of the semiconductor memory apparatus 1 through the data pad block 20. In FIG. 2, only four data bits D0 to D3 are inputted through the data pad block 20, but the number of data bits is not restricted thereto. In other words, the number of inputted data bits may vary depending on the scheme of the semiconductor memory apparatus 1. The embodiment may be applied to any number of data bits.

In response to the test mode signal TXDQ and the multi-bit test signals TBL<1:3>, the write driver unit 300 generates first to fourth input data bits Din0 to Din3 from the first to fourth data bits D0 to D3 and then transfers the input data bits Din0 to Din3 to first to fourth bit lines BL0 to BL3, respectively. The input data transferred to the bit lines BL0 to BL3, respectively, may be stored in a memory cell (not shown) coupled to the corresponding bit lines BL0 to BL3, respectively. The write driver unit 300 performs a normal write operation or the write operation of the multi-bit test based on whether the test mode signal TXDQ is enabled or not. When the test mode signal TXDQ is disabled, the write driver unit 300 performs the normal write operation. In the normal write operation, the write driver unit 300 amplifies and drives the data D0 to D3 inputted through the data pad block 20, which transfers the driven data to the corresponding bit lines BL0 to BL3, respectively. For example, the write driver unit 300 generates the first input data Din0 from the first data D0 and transfers the first input data Din0 to the first bit line BL0. Similarly, the write driver 300 generates the second input data Din1 from the second data D1 and transfers the second input data Din1 to the second bit line BL1. Likewise, it generates the third and fourth input data Din1 and Din3 from the third and fourth data D2 and D3 and transfers the third and fourth input data Din1 and Din3 to the third and fourth bit lines BL2 and BL3, respectively.

When the test mode signal TXDQ is enabled, the semiconductor memory apparatus 1 performs the write operation of the multi-bit test. In the multi-bit test operation, a single data bit, i.e., the first data bit D0, is inputted through the data pad block 20. The write driver unit 300 receives the first data D0 and then generates the first to fourth input data bits Din0 to Din3 from the first data bit D0 in response to the multi-bit test signals TBL<1:3>. The first to fourth input data bits Din0 to Din3 may be stored in the memory cell (not shown) through the first to fourth bit lines BL0 to BL3, respectively. For example, in response to the multi-bit test signals TBL<1:3>, the write driver unit 300 may amplify and drive the first data bit D0 to generate the first input data bit Din0 and then inversely or non-inversely drive the first data bit D0 to generate the second to fourth input data bits Din1 to Din3. Therefore, in the multi-bit test operation, the logic level of the second to fourth input data Din1 to Din3 generated from the write driver unit 300 may vary depending on the logic level of the multi-bit test signals TBL<1:3>.

FIG. 3 is a block diagram showing a configuration of the multi-bit test signal generating unit 100 of FIG. 2. As shown in FIG. 3, the multi-bit test signal generating unit 100 includes first to third signal generating units 110 to 130. In response to the write signal WT and the test mode signal TXDQ, the first signal generating unit 110 receives the address signal A<0>, and generates the multi-bit test signal TBL<1> based on the address signal A<0> logic level. Similarly, in response to the same write signal WT and the test mode signal TXDQ, the second and third signal generating units 120 and 130 receive the address signals A<1:2>, respectively, and generate the multi-bit test signals TBL<2:3>, respectively,. As shown in FIG. 3, the multi-bit test signal generating unit 100 may further include address buffers 41 to 43. In this case, the address signals A<0:2> may be amplified by the address buffers 41 to 43, respectively, and then be inputted to the first to third signal generating units 110 to 130, respectively.

In addition, FIG. 3 shows a configuration for the first signal generating unit 110 of the semiconductor memory apparatus 1. As shown in FIG. 3, the first signal generating unit 110 includes an address driving unit 111, an address latch unit 112, and an output unit 113. The address driving unit 111 drives the address signal A<0> if the write signal WT is enabled. The address latch unit 112 latches an output of the address driving unit 111. In response to the test mode signal TXDQ, the output unit 113 receives an output of the address latch unit 112 and generates the multi-bit test signal TBL<1>.

The address driving unit 111 includes a first inverter IV1 and a tri-state inverter TIV1. The first inverter IV1 inverts the write signal WT. If the write signal WT is enabled, the tri-state inverter TIV1 may inversely drive and output the address signal A<0> in response to the write signal WT and an output of the first inverter IV1. Therefore, in response to the write signal WT, the address driving unit 111 may drive the address signal A<0> when the write operation is performed. The address latch unit 112 includes second and third inverters IV2 and IV3, and latches the output of the address driving unit 111.

The output unit 113 includes a first NAND gate ND1 and a fourth inverter IV4. The first NAND gate ND1 receives the test mode signal TXDQ and the output of the address latch unit 112. The fourth inverter IV4 inverts an output of the first NAND gate ND1 to generate the multi-bit test signal TBL<1>. Therefore, when the test mode signal TXDQ is enabled and thus the semiconductor memory apparatus 1 performs the multi-bit test operation, the output unit 113 may output the output of the address latch unit 112 as the multi-bit test signal TBL<1>. The second and third signal generating units 120 and 130, respectively, have substantially the same configuration and the same operation as the first signal generating unit 110. Therefore, a repeated description will be omitted here.

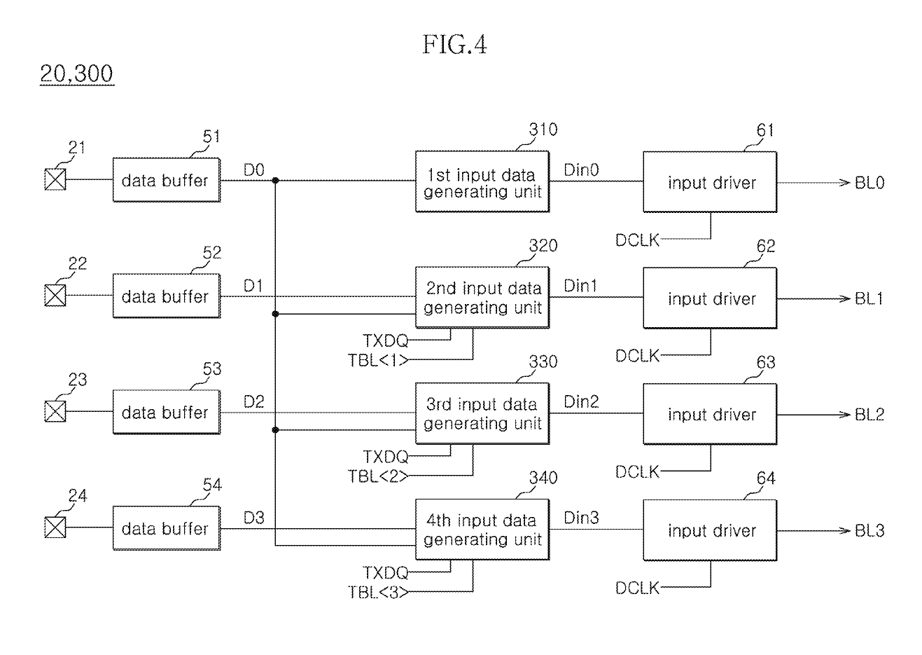

FIG. 4 is a block diagram showing a configuration of the data pad block 20 and the write driver unit 300 of FIG. 2. As shown in FIG. 4, the data pad block 20 includes first to fourth data pads 21 to 24, which are used as input paths of the first to fourth data bits D0 to D3, respectively.

The write driver unit 300 includes first to fourth input data bits generating units 310 to 340. In the normal write operation, the first to fourth input data generating units 310 to 340 generate the first to fourth input data bits Din0 to Din3 from the first to fourth data bits D0 to D3 inputted through the first to fourth data pads 21 to 24, respectively. The first to fourth input data generating units then transfer the first to fourth input data bits Din0 to Din3 to the first to fourth bit lines BL0 to BL3, respectively.

The first input data generating unit 310 receives the first data D0 and then amplifies and drives the first data D0 to generate the first input data Din0.

The second input data generating unit 320 receives the first data bit D0 and the second data bit D1, and then generates the second input data bit Din1 from the first data bit D0 or generates the second input data bit Din1 from the second data bit D1′, in response to the test mode signal ‘TXDQ’. In addition, the second input data generating unit 320 may inversely drive or non-inversely drive the first data bit D0 to generate the second input data bit Din1′ in response to the multi-bit test signal ‘TBL<1>’ when the second input data ‘Din1’ is generated from the first data ‘D0’.

The third input data generating unit 330 receives the first data bit D0 and the third data bit D2, and then generates the third input data bit Din1 from the first data bit D0 or generates the third input data bit Din1 from the third data bit D2′, in response to the test mode signal ‘TXDQ’. Likewise, the third input data generating unit 330 may inversely or non-inversely drive the first data bit D0 and generate the third input data bit Din1′ in response to the multi-bit test signal ‘TBL<2>’ when the third input data bit Din1 is generated from the first data bit D0.

The fourth input data generating unit 340 receives the first data bit D0 and the fourth data bit D3, and then generates the fourth input data bit Din3 from the first data bit D0 or generates the fourth input data bit Din3 from the fourth data bit D3, in response to the test mode signal ‘TXDQ’. In addition, the fourth input data bit generating unit 340 may inversely or non-inversely drive the first data bit D0 to generate the fourth input data bit Din3 in response to the multi-bit test signal TBL<3> when the fourth input data bit Din3 is generated from the first data D0.

As shown in FIG. 4, the semiconductor memory apparatus 1 may further comprise a plurality of data buffers 51 to 54. The data buffers 51 to 54 amplify and output the first to fourth data bits D0 to D3, which are inputted though the data pads 21 to 24, respectively.

In addition, the semiconductor memory apparatus 1 may further include a plurality of input drivers 61 to 64. The input drivers 61 to 64 synchronize the first to fourth input data Din0 to Din3 generated from the first to fourth input data generating units 310 to 340 with a data clock signal DCLK to transfer the synchronized data to the first to fourth bit lines BL0 to BL3, respectively.

FIG. 5 is a diagram showing a configuration of the second input data generating unit 320 of FIG. 4. As shown in FIG. 5, the second input data generating unit 320 includes a first non-inversion driving unit 321, a second non-inversion driving unit 322, a first inversion driving unit 323, a first pass-gate 324, and a second pass-gate 325. The first non-inversion driving unit 321 non-inversely drives the second data D1. The second non-inversion driving unit 322 non-inversely drives the first data D0 in response to the multi-bit test signal TBL<1>. The first inversion driving unit 323 inversely drives the first data D0 in response to the multi-bit test signal TBL<1>. In response to the test mode signal TXDQ and its inverted form though inverter 326, the first pass-gate 324 outputs first non-inversion driving unit 321 as the second input data bit Din1. In response to the test mode signal TXDQ and its inverted form though inverter 327, the second pass-gate 325 outputs either the second non-inversion driving unit 322 or the first inversion driving unit 323 as the second input data bit Din1. Therefore, the second input data generating unit 320 may generate the second input data bit Din1 from the second data bit D1 during the normal write operation of the semiconductor memory apparatus 1. It may also generate the second input data bit Din1 from the first data D0 during the write operation of the multi-bit test of the semiconductor memory apparatus 1.

The test mode signal TXDQ is disabled in the normal write operation of the semiconductor memory apparatus 1. Therefore, the first pass-gate 324 is turned on, while the second pass-gate 325 is turned off. Therefore, the second input data generating unit 320 may drive the second data bit D1 to generate the second input data bit Din1. On the other hand, the test mode signal TXDQ is enabled during the multi-bit test operation of semiconductor apparatus 1. Therefore, first pass-gate 324 is turned off, while the second pass-gate 325 is turned on. Therefore, the second input data generating unit 320 may generate the second input data bit Din1 from the first data D0 bit. Since either the second non-inversion driving unit 322 or the first inversion driving unit 323 may be enabled in response to the multi-bit test signal TBL<1>, the first data D0 may be non-inversely or inversely driven by either the second non-inversion driving unit 322 or the first inversion driving unit 323. The driven data may then be outputted as the second input data bit Din1.

The third and fourth input data generating units 330 and 340 in FIG. 4 have substantially the same configuration as the second input data generating unit 320 and generate the third and fourth input data bits Din1 and Din3, respectively. The first input data generating unit 310, however, may be implemented with only the first non-inversion driving unit 321 of the second input data generating unit 320, unlike the second to fourth input data generating units 320 to 340.

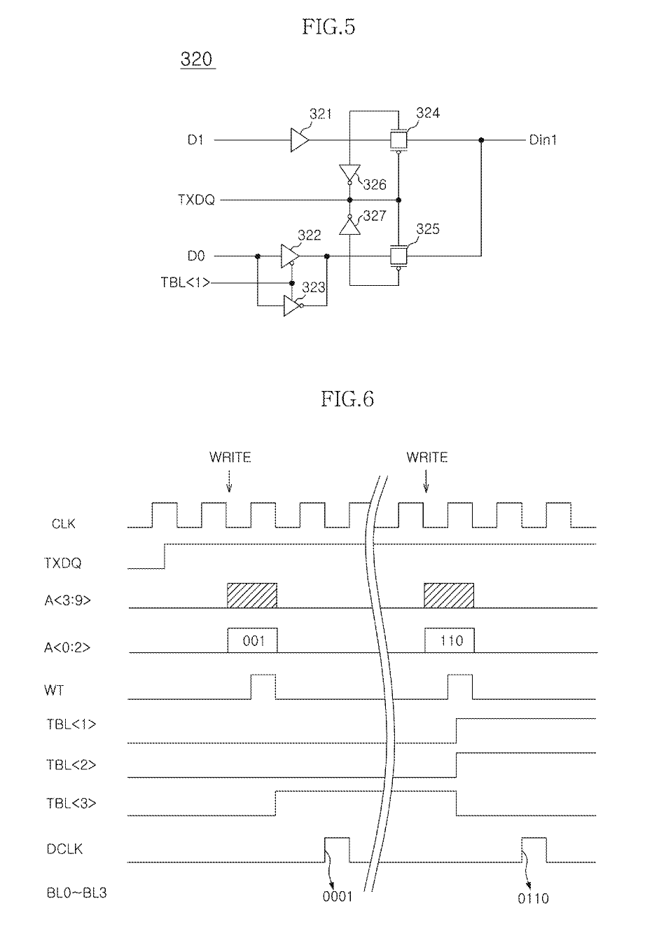

FIG. 6 is a timing diagram showing an operation of the semiconductor memory apparatus 1 according to the embodiment. Hereinafter, an operation of the semiconductor memory apparatus 1 will be described with reference to FIGS. 2 to 6.

If the test mode signal TXDQ is enabled, the semiconductor memory apparatus 1 performs the multi-bit test operation. In the multi-bit test operation, address signals A<3:9> and address signals A<0:2> are inputted at the same time the write command WRITE is inputted. The address signals A<3:9> are used in both the active and write operations, whereas the address signals A<0:2> are only used in the active operation. Hereinafter in this embodiment for example only, the address signals A<0:2> having a logic level “0, 0, 1” are inputted when a first write command WRITE is inputted and the address signals A<0:2> having a logic level “1, 1, 0” are inputted when a second write command WRITE is inputted.

If the write command WRITE and the address signals A<3:9> and A<0:2> are inputted, the semiconductor memory apparatus 1 internally generates the write signal WT as mentioned above. Based on the address signals A<0:2>, the multi-bit test signal generating unit 100 generates the multi-bit test signals TBL<1:3> if the write signal WT is enabled,. That is, since the address signals A<0:2> have the logic level “0, 0, 1” as mentioned above, the multi-bit test signal generating unit 100 generates the multi-bit test signals TBL<1:3> having the logic level “0, 0, 1”. At this time, if the first data D0 having a logic level “0” is inputted though the data pad 21, the first input data generating unit 310 of the write driver unit 300 generates the first input data Din0 having a logic level “0”. Since the second input data generating unit 320 receives the multi-bit test signal TBL<1> having the logic level “0”, the second input data generating unit 320 non-inversely drives the first data D0 to generate the second input data Din1 having a logic level “0”. Since the third input data generating unit 330 receives the multi-bit test signal TBL<2> having the logic level “0”, the third input data generating unit 330 non-inversely drives the first data D0 to generate the third input data Din1 having a logic level “0”. Since the fourth input data generating unit 340 receives the multi-bit test signal TBL<3> having the logic level “1”, the fourth input data generating unit 340 inversely drives the first data D0 to generate the fourth input data Din3 having a logic level “1”. Afterwards, if the data clock signal DCLK is enabled, the input drivers 61 to 64 transfer the first to fourth input data Din0 to Din3 having the logic level “0, 0, 0, 1” to the first to fourth bit lines BL0 to BL3, respectively. The data of the logic level “0, 0, 0, 1” transferred to the first to fourth bit lines BL0 to BL3 are stored in the memory cell of the semiconductor memory apparatus 1.

If the second write command WRITE and the address signals A<0:2> having the logic level “1, 1, 0” are inputted as mentioned above, the multi-bit test signal generating unit 100 generates the multi-bit test signals TBL<1:3> having a logic level “1, 1, 0”. At this time, if the first data D0 having the logic level “0” is inputted though the data pad 21, the first input data generating unit 310 of the write driver unit 300 generates the first input data Din0 having the logic level “0”. Since the second input data generating unit 320 receives the multi-bit test signal TBL<1> having the logic level “1”, the second input data generating unit 320 inversely drives the first data D0 to generate the second input data Din1 having a logic level “1”. Since the third input data generating unit 330 receives the multi-bit test signal TBL<2> having the logic level “1”, the third input data generating unit 330 inversely drives the first data D0 to generate the third input data Din1 having a logic level “1”. Since the fourth input data generating unit 340 receives the multi-bit test signal TBL<3> having the logic level “0”, the fourth input data generating unit 340 non-inversely drives the first data D0 to generate the fourth input data Din3 having a logic level “0”. Afterwards, if the data clock signal DCLK is enabled, the input drivers 61 to 64 transfer the first to fourth input data Din0 to Din3 having the logic level “0, 1, 1, 0” to the first to fourth bit lines BL0 to BL3, respectively. The data of the logic level “0, 1, 1, 0” transferred to the first to fourth bit lines BL0 to BL3 are stored in the memory cell of the semiconductor memory apparatus 1.

Therefore, the semiconductor memory apparatus 1 according to the embodiment does not need such an operation that an extra test signal is inputted and the multi-bit test signals TBL<1:3> are reset or set. Rather, the semiconductor memory apparatus 1 may generate the multi-bit test signals TBL<1:3> by using the address signals A<0:2> inputted to the semiconductor memory apparatus 1 and may store data having a desired logic level in a memory cell coupled to the bit line. Therefore, the semiconductor memory apparatus 1 may perform the test operation by changing an input of the address signal and storing data which have various patterns, thereby capable of substantially reducing a test time.

While certain embodiments have been described above, it will be understood to those skilled in the art that the embodiments described are by way of example only. Accordingly, the device and method described herein should not be limited based on the described embodiments. Rather, the apparatus described herein should only be limited in light of the claims that follow when taken in conjunction with the above description and accompanying drawings.

What is claimed is:

1. A semiconductor memory apparatus, comprising:
a multi-bit test signal generating device configured to receive an address signal and generate a multi-bit test signal based on the address signal when a multi-bit test write operation is performed.

2. The semiconductor memory apparatus according to claim 1, wherein the multi-bit test signal generating device includes:
an address driving unit configured to drive the address signal in response to a write signal;
an address latch unit configured to latch an output of the address driving unit; and
an output unit configured to generate the multi-bit test signal in response to a test mode signal and an output of the address latch unit.

3. The semiconductor memory apparatus according to claim 2, wherein the write signal is configured to be enabled in the write operation.

4. The semiconductor memory apparatus according to claim 2, wherein the test mode signal informs the semiconductor memory apparatus to perform the multi-bit test operation.

5. A semiconductor memory apparatus comprising:
a multi-bit test signal generating unit configured to receive an address signal to generate a multi-bit test signal; and
a write driver unit configured to receive a first data signal, a second data signal and the multi-bit test signal to generate a first input data signal and a second input data signal.

6. The semiconductor memory apparatus according to claim 5, wherein the multi-bit test signal generating unit is configured to generate the multi-bit test signal based on the address signal in a multi-bit test write operation.

7. The semiconductor memory apparatus according to claim 6, wherein the address signal is configured to be used in an active operation of the semiconductor memory apparatus but not used in a write operation of the semiconductor memory apparatus.

8. The semiconductor memory apparatus according to claim 5, wherein the multi-bit test signal generating unit includes:
an address driving unit configured to drive the address signal in response to a write signal;
an address latch unit configured to latch an output of the address driving unit; and
an output unit configured to generate the multi-bit test signal in response to a test mode signal and an output of the address latch unit.

9. The semiconductor memory apparatus according to claim 7, wherein the write driver unit includes:
a first input data generating unit configured to drive the first data signal to generate the first input data signal; and
a second input data generating unit configured to generate the second input data signal from either one of the first and second data signals in response to the test mode signal.

10. The semiconductor memory apparatus according to claim 9, wherein the second input data generating unit is configured to inversely drive or non-inversely drive the first data signal to generate the second input data signal in response to the multi-bit test signal when the second input data signal is generated from the first data signal.

11. A semiconductor memory apparatus comprising:
a multi-bit test signal generating unit configured to generate a plurality of multi-bit test signals in response to a plurality of address signals; and
a write driver unit configured to inversely drive or non-inversely drive a single data signal to generate a plurality of input data signal in response to the plurality of multi-bit test signals.

12. The semiconductor memory apparatus according to claim 11, wherein the plurality of address signals are configured to be used in an active operation of the semiconductor memory apparatus but not used in a write operation of the semiconductor memory apparatus.

13. The semiconductor memory apparatus according to claim 11, wherein the multi-bit test signal generating unit is configured to generate the plurality of multi-bit test signals based on the plurality of address signals in a write operation of a multi-bit test.

14. The semiconductor memory apparatus according to claim 11, wherein the multi-bit test signal generating unit includes a plurality of signal generating units each configured to receive a write signal, a test mode signal, and a corresponding address signal of the plurality of address signals to generate the multi-bit test signal.

15. The semiconductor memory apparatus according to claim 14, wherein each of the plurality of signal generating units includes:
an address driving unit configured to drive the corresponding address signal in response to the write signal;
an address latch unit configured to latch an output of the address driving unit; and
an output unit configured to generate the multi-bit test signal in response to the test mode signal and an output of the address latch unit.

16. The semiconductor memory apparatus according to claim 11, wherein the write driver unit includes a plurality of input data generating units configured to commonly receive the data signal and to inversely drive or non-inversely drive the data signal to generate the plurality of input data signals in response to the multi-bit test signal.

17. A multi-bit test method for a semiconductor memory apparatus comprising:
generating a multi-bit test signal based on an address signal which is used in an active operation of the semiconductor memory apparatus but not used in a write operation of the semiconductor memory apparatus, if a test mode signal and a write signal are enabled;
inversely driving or non-inversely driving a first data signal to generate a plurality of input data signals in response to the multi-bit test signal; and
transferring the plurality of input data signals to a plurality of bit lines.

18. The test method according to claim 17, wherein the test mode signal is configured to be a signal which informs the semiconductor memory apparatus to perform the multi-bit test operation.

19. The test method according to claim 17, wherein the write signal is configured to be enabled in the write operation of the semiconductor memory apparatus.

20. The test method according to claim 17, wherein generating the multi-bit test signal comprises:
driving and latching the address signal if the write signal is enabled; and
logically combining the test mode signal and the driven address signal to generate the multi-bit test signal.
